(19) United States
(12) Patent Application Publication
(10) Pub. No.: US 2008/0188074 A1
(43) Pub. Date: Aug. 7, 2008

(54) Peeling-free porous capping material

(76) Inventors: I-I Chen, Hsinchu City (TW); Fang Wen Tsai, Hsinchu (TW); Zhen-Cheng Wu, Hsinchu (TW); Tien-I Bao, Hsin-Chu (TW); Shwang-Ming Jeng, Hsin-Chu (TW); Chen-Hua Yu, Hsin-Chu (TW)

Correspondence Address: SLATER & MATSIL, L.L.P., 17950 PRESTON ROAD, SUITE 1000, DALLAS, TX, 75252, US

(21) Appl. No.: 11/728,623

(22) Filed: Mar. 27, 2007

Related U.S. Application Data
(60) Provisional application No. 60/899,703, filed on Feb. 6, 2007.

(51) Int. Cl. H01L 21/4763

(52) U.S. Cl. 438/623; 438/637

(57) ABSTRACT

A method for forming a cap layer for an interconnect structure is provided. The method includes providing a substrate; depositing a low-k dielectric layer comprising a first porogen over the substrate; depositing a low-k cap layer comprising a second porogen on the low-k dielectric layer; and curing the low-k dielectric layer and the low-k cap layer simultaneously to remove the first and the second porogens, so that a first porosity in the low-k dielectric layer and a second porosity in the low-k cap layer are created. The second porosity is preferably less than the first porosity. Preferably, the low-k dielectric layer and the low-k cap layer comprise a common set of precursors and porogens, and are in-situ performed.

This application claims priority to provisional patent application Ser. No. 60/899,703 filed Feb. 6, 2007, and entitled “Peeling-Free Porous Capping Material,” which application is incorporated herein by reference.

### TECHNICAL FIELD

This invention relates generally to integrated circuits, and more particularly to methods for forming semiconductor interconnect structures.

### BACKGROUND

High-density integrated circuits, such as very large scale integration (VLSI) circuits, are typically formed with multiple metal interconnects to serve as three-dimensional wiring line structures. The purpose of multiple interconnects is to properly link densely packed devices together. With increasing levels of integration, a parasitic capacitance effect between the metal interconnects, which leads to RC delay and cross talk, increases correspondingly. In order to reduce the parasitic capacitance and increase the conduction speed between the metal interconnections, low-k dielectric materials are commonly employed to form inter-layer dielectric (ILD) layers and inter-metal dielectric (IMD) layers.

Low-k dielectric materials typically have low mechanical strength, thus are prone to damage in the subsequent chemical mechanical polish. Particularly, peeling occurs between the low-k dielectric material and the overlying anti-reflective coating layer. Therefore, cap layers are often formed. One of the commonly used cap layer materials is tetra ethyl ortho silicate (TEOS). TEOS works with low-k dielectric materials having k values of greater than about 3.9. However, for 65 nm technology or below, low-k materials with even lower k values, such as extreme low-k dielectric materials (ELK), the material mismatch between TEOS and ELK increases, the interface between TEOS and ELK becomes weaker, and peeling occurs.

Another commonly used cap material is formed by plasma treatment and curing of the low-k dielectric material, thus turning a top layer of the low-k dielectric layer into a cap layer. There are two possible sequences for performing the plasma treatment and the curing, but neither of them provides satisfactory results. If the low-k dielectric material is plasma-treated and then cured, a dense layer is formed on the top of the low-k dielectric layer as a result of the plasma treatment, which will prevent the subsequently formed curing from driving porogen out of the low-k dielectric layer. Conversely, if the low-k dielectric material is cured and then plasma treated, the plasma may damage the low-k dielectric layer and increase the k value.

Therefore, there is the need for novel cap layer materials that overcome the above-discussed shortcomings.

### SUMMARY OF THE INVENTION

In accordance with one aspect of the present invention, a method for forming an interconnect structure based on a low-k dielectric layer is provided. The method includes providing a substrate; depositing a low-k dielectric layer comprising a first porogen over the substrate; depositing a low-k cap layer comprising a second porogen on the low-k dielectric layer; and curing the low-k dielectric layer and the low-k cap layer simultaneously to remove the first and the second porogens so that a first porosity in the low-k dielectric layer and a second porosity in the low-k cap layer are created. Preferably, the low-k cap layer and the low-k dielectric layer are formed of a same material, and/or the first porogen and the second porogen are formed of a same material.

In accordance with another aspect of the present invention, the method includes providing a substrate; depositing a low-k dielectric layer comprising a porogen over the substrate; in-situ depositing a low-k cap layer comprising the porogen on the low-k dielectric layer, wherein the low-k dielectric layer and the low-k cap layer are formed of the same precursors; and curing the low-k dielectric layer and the low-k cap layer simultaneously to remove the porogen and to create a first porosity in the low-k dielectric layer and a second porosity in the low-k cap layer, wherein the second porosity is less than the first porosity.

In accordance with another aspect of the present invention, a semiconductor structure includes a substrate; a first low-k dielectric layer over the substrate; a low-k cap layer formed of a low-k dielectric material, wherein the low-k dielectric layer and the low-k cap layer comprise a common set of molecules, and wherein a first porosity in the low-k dielectric layer is greater than a second porosity in the low-k cap layer.

The advantageous features of the present invention includes simplified processes and low cost due to the in-situ formed low-k dielectric layer and low-k cap layer, good adhesion between the low-k cap layer and the underlying low-k dielectric layer, and good adhesion between the low-k cap layer and the overlying ARC layer, thus peeling problems are substantially minimized and may be eliminated. Additionally, other problems such as difficulty in removing porogen, and damage to the low-k dielectric layer, may also be eliminated.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 5 are cross-sectional views of intermediate stages in the manufacturing of a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A method for forming a cap layer for an interconnect structure is provided. The intermediate stages of manufacturing a preferred embodiment of the present invention are illustrated. Throughout the various views and illustrative embodiments of the present invention, like reference numbers are used to designate like elements.

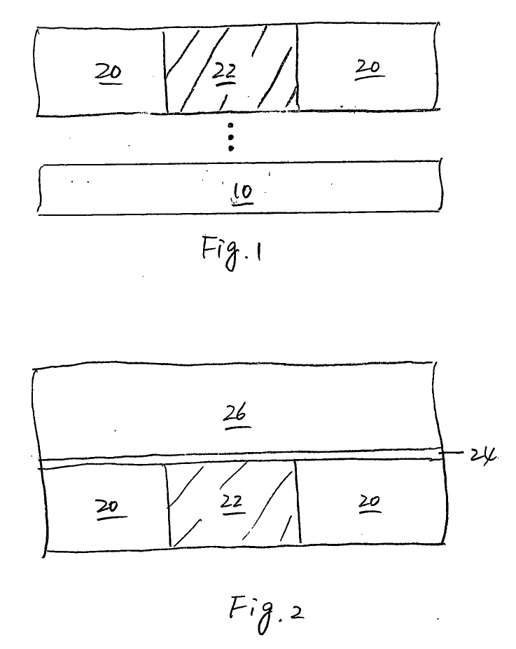

In semiconductor integrated circuit manufacturing processes, semiconductor devices are formed in or on a substrate. Metal lines are then used to interconnect devices. Metal lines may be formed in different metallization layers and separated by dielectric layers, such as inter-layer dielectrics (ILD) and inter-metal dielectrics (IMD), and the layers are interconnected by vias. The dielectric layers preferably have low k values, so that parasitic capacitances between the conductive lines are low. FIGS. 1 through 5 illustrate a single damascene process as an example to explain the concept of the present invention. One skilled in the art will realize that the method for forming the cap layer is readily available for other methods of forming interconnect structures.

FIG. 1 illustrates a portion of a substrate 10, over which a conductive line 22 is formed in a dielectric layer 20. For simplicity, substrate 10 is not shown in subsequent drawings. The conductive line 22 is preferably a metal comprising copper, tungsten, aluminum, silver, gold, and the like. It can also be formed of other conductive materials such as doped polysilicon. The conductive line 22 is typically connected to another feature (not shown), such as a via or a contact plug. The dielectric layer 20 may be an inter-layer dielectric (ILD) layer, or an inter-metal dielectric (IMD) layer.

FIG. 2 illustrates the formation of an etch stop layer (ESL) 24 and a low-k dielectric layer 26 on the conductive line 22 and the dielectric layer 20. Preferably, the ESL 24 comprises dielectric materials such as nitride, SiCN, SiCO, and the like. Low-k dielectric layer 26 provides insulation between the metallization layer in which the conductive line 22 resides and an overlying metallization layer (not shown). Low-k dielectric layer 26 preferably has a dielectric constant (k) value of lower than about 3.5, and more preferably lower than about 2.5. The preferred materials include organosilicate glass, carbon-containing materials, and combinations thereof. The low-k dielectric layer 26 may be deposited using a chemical vapor deposition (CVD) method, preferably plasma enhanced CVD (PECVD), although other commonly used deposition methods such as low pressure CVD (LPCVD) and atomic layer CVD (ALCVD) can also be used. If formed using 65 nm technology, the preferred thickness of the low-k dielectric layer 26 is between about 3000 Å and about 5000 Å, and more preferably about 4500 Å. However, one skilled in the art will realize that the dimensions of the features in the integrated circuit will reduce when smaller-scale technologies are used.

In an exemplary embodiment, the low-k dielectric layer 26 is formed using PECVD. The process conditions include a temperature of between about 300° C. and about 400° C., a chamber pressure of between about 5 Torr and about 9 Torr, a RF power of between about 300 W and about 900 W, an oxygen flow of between about 50 sccm and about 1000 sccm, a helium flow of between about 100 sccm and about 3000 sccm, and an organic porogen flow of between about 50 mgm and 3000 mgm. Preferably, a spacing between a faceplate and a heater is between about 100 mil to about 600 mil.

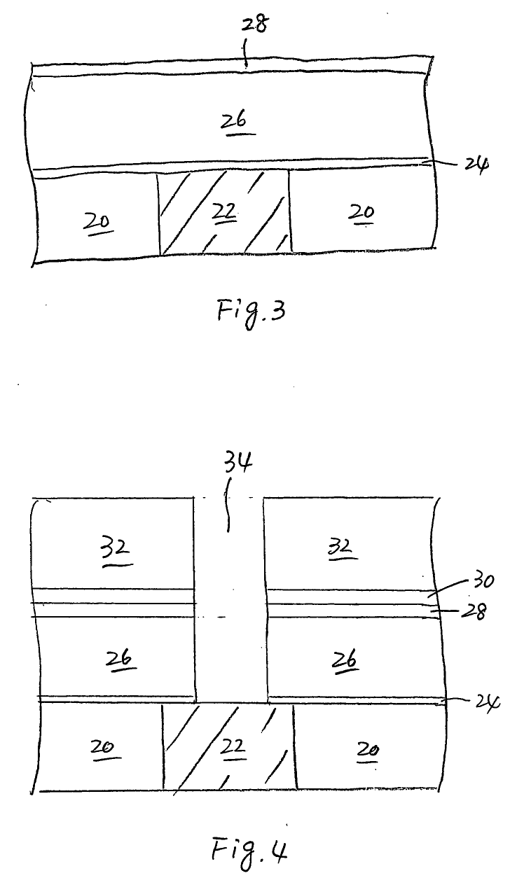

Referring to FIG. 3, a second low-k dielectric layer 28, also alternatively referred to as a low-k cap layer 28, is formed on the low-k dielectric layer 26. In the preferred embodiment, low-k cap layer 28 and low-k dielectric layer 26 are formed with common precursors, thus the resulting low-k cap layer 28 and low-k dielectric layer 26 have substantially similar materials. Preferably, over than about 85 percent, and more preferably, over than about 95 percent, of the materials in low-k cap layer 28 and low-k dielectric layer 26 are the same. Additionally, low-k cap layer 28 and low-k dielectric layer 26 preferably comprise the same type of porogens, such as CₓH_{y}-containing materials including C₂H₄, C₃H₆, hexamethyldisilazane (HMDS), and the like. Low-k cap layer 28 preferably has a thickness of less than about 500 Å, and more preferably between about 50 Å and about 450 Å.

In the resulting structure, low-k cap layer 28 comprises less porogen than low-k dielectric layer 26. Preferably, low-k cap layer 28 comprises less than about 25 percent porogen, and low-k dielectric layer 26 comprises less than about 35 percent porogen. More preferably, the porogen percentage in low-k cap layer 28 is less than that in the low-k dielectric layer 26 by a difference of greater than about 5 percent. As a result, the mechanical strength of the low-k cap layer 28 will be greater than the mechanical strength of the low-k dielectric layer 26. Also, the k value of the low-k cap layer 28 is slightly greater than that of the low-k dielectric layer 26, for example, with a difference of about 0.2 or greater. Preferably, low-k cap layer 28 has a k value of less than about 3.7, and more preferably less than about 2.7.

In order to achieve the above-specified property differences, process conditions need to be slightly different. In the preferred embodiment, the low-k cap layer 28 is formed in-situ with the low-k dielectric layer 26 and is formed using the same method. Therefore, after the deposition of the low-k dielectric layer 26, the process conditions are preferably adjusted to what are suitable for producing less porogen content and greater hardness, and the formation of low-k cap layer 28 continues. For example, low-k cap layer 28 is preferably deposited using a lower RF power than used for the low-k dielectric layer 26. Additionally, low-k cap layer 28 is preferably deposited with a lower porogen-to-precursor ratio than the low-k dielectric layer 26. In an exemplary embodiment the porogen-to-precursor ratio for forming low-k dielectric layer 26 is between about 0.9 and about 2.5, while the porogen-to-precursor ratio for forming low-k cap layer 28 is between about 0.5 and about 1.4. One skilled in the art will realize that other process conditions, such as the chamber pressure or partial pressure, also affect the properties of the low-k dielectric layers 26 and 28, and optimum process conditions can be found through routine experiments.

In an exemplary embodiment, the process conditions for forming low-k cap layer 28 include a temperature of between about 200° C. and about 400° C., a chamber pressure of between about 3 Torr and about 9 Torr, a RF power of between about 400 W and about 650 W, an oxygen flow of between about 50 sccm and about 1000 sccm, a helium flow of between about 100 sccm and about 3000 sccm, an organic porogen flow of between about 50 mgm and 3000 mgm, and a spacing between a faceplate and a heater of about 100 mil to about 500 mil.

A curing process is then performed. The curing process can be performed using commonly used curing methods, such as eBeam curing, ultraviolet (UV) curing, thermal curing, SCCO₂ curing, and the like, and may be performed in a production tool that is also used for PECVD, atomic layer deposition (ALD), LPCVD, etc. More than one curing method can be combined to achieve better effects.

The curing preferably has two functions: driving porogen out of low-k dielectric layers 26 and 28 and improving the mechanical property of the respective low-k materials. In the preferred embodiment, the curing processes for removing porogen and improving the mechanical property are performed in a continuous curing step. In other embodiments, the first curing process is primarily for removing porogen, while the second curing process is primarily for improving mechanical properties, although each of the curing processes will serve both functions. If two curing processes are used, the first and the second curing process may be performed by a same method or different methods. In an exemplary embodiment wherein UV curings are performed, the first curing may be performed with a wavelength greater than a respective wavelength of the second curing. In an exemplary embodiment, the first curing has a wavelength of between about 250 nm and about 280 nm, and the second curing has a wavelength of between about 200 nm and about 300 nm. Alternatively, the first and the second curing processes may be performed using the same wavelengths.

Preferably, the curing processes are performed with the presence of bond-repairing materials, preferably carbon-containing materials. The preferred bond-repairing materials include materials in the silane group, such as (CH₃)₃SiH (also known as 3 MS or trimethylsilane) and/or Si(OC₂H₅)₂(CH₃)H (also known as DEMS), and the like. Other materials comprising carbon and hydrogen, often expressed as CₓH_{y}, can also be used for curing. The bond-repairing materials supply carbon and hydrogen, which are useful for restoring the bonds of the low-k materials. During the curing, carbon and hydrogen form bonds with the low-k dielectric material, resulting in improved mechanical properties.

Since the low-k dielectric layer 26 and the low-k cap layer 28 are formed of similar materials and have similar structures, both low-k dielectric layer 26 and the overlying low-k cap layer 28 are cured simultaneously. The porogen in low-k dielectric layer 26 can thus easily penetrate the low-k cap layer 28, while if the low-k cap layer 28 uses different materials from low-k dielectric layer 26, porogen from the low-k dielectric layer 26 is likely to be blocked by the low-k cap layer 28. In alternative embodiments, low-k dielectric layer 26 and the low-k cap layer 28 may be cured separately, for example, by curing low-k dielectric layer 26 before the formation of low-k cap layer 28.

Since the porogen content of the low-k cap layer 28 is less than that of the low-k dielectric layer 26 due to adjusted process conditions, after porogen is removed, the resulting low-k cap layer 28 has a smaller porosity, hence better mechanical properties, than the low-k dielectric layer 26. Preferably, the porosity of the low-k dielectric layer 26 is less than about 35 percent, and the porosity of the low-k cap layer 28 is less than about 25 percent. Even more preferably, the porosity in low-k cap layer 28 is less than that in low-k dielectric layer 26 by about 1.2 percent.

Using the previously discussed method, sample structures have been formed and measured. Preferably, by carefully adjusting process conditions as previously discussed, the hardness of the low-k cap layer 28 can be greater than the hardness of the low-k dielectric layer 26 by about 10 percent or even higher. For example, in sample structures made using the preferred embodiment, the low-k dielectric layers 26 have hardness values of less than about 1.6 Gpa, while the hardness of the low-k cap layers 28 are greater than about 1.8 Gpa, and sometimes even greater than about 1.9 GPa or 2.0 GPa. With significantly greater hardness, the low-k cap layer 28 can perform the capping function protecting the underlying low-k dielectric material from damage caused by CMP.

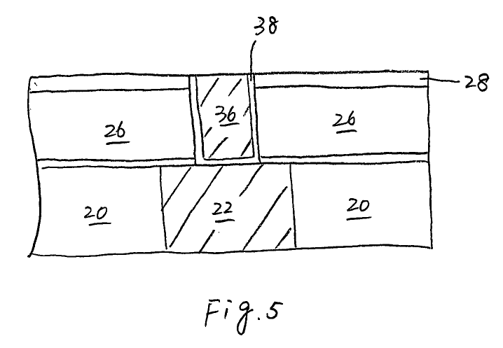

Referring to FIG. 4, a bottom anti-reflective coating (BARC) 30 and a photo resist 32 are formed and patterned. BARC 30 is preferably nitrogen free. The low-k cap layer 28 and low-k dielectric layer 26 are then etched, forming an opening 34. Opening 34 may be a via opening or a trench opening. As is known in the art, the opening 34 can be formed by etching or ashing the low-k dielectric layer 26. The etching/ashing process stops at the ESL 24. Next, the exposed portion of the ESL 24 is etched. Because the ESL 24 is quite thin relative to the low-k dielectric layer 26, process control and end-point detection are much more closely controlled, thus limiting the likelihood of over-etching through the underlying conductive line 22. BARC 30 and photo resist 32 are then removed. In some embodiments, it may be preferable to over-etch ESL 24 in order to form a recess in conductive line 22 (not shown).

Referring to FIG. 5, the opening 34 is filled, forming a metal feature 36. In the preferred embodiment, the filling material comprises metals such as copper, aluminum, tungsten, silver, gold, combinations thereof and/or other well-known alternatives. Preferably, a barrier layer 38 is formed before the formation of the metal feature 36, and the barrier layer 38 is formed of a material comprising materials such as titanium, titanium nitride, tantalum, tantalum nitride, silicon carbide, silicon oxycarbide, and the like. The barrier layer 38 prevents the metal material, particularly copper, from diffusing into the low-k dielectric layer 26 and causing circuit failure. A chemical mechanical polish (CMP) is then performed to remove excess materials.

The low-k cap layer 28 has a good adhesion to the BARC 30. During the CMP process, no peeling has been observed at the interface between the BARC 30 and the underlying cap layer 28.

In the preferred embodiment of the present invention, the formation of low-k dielectric layer 26 and low-k cap layer 28 comprise common precursors and common porogens, and are in-situ formed. In other embodiments, low-k dielectric layer 26 and low-k cap layer 28 are formed of the same precursor but different porogens. In yet other embodiments, low-k dielectric layer 26 and low-k cap layer 28 are formed of different precursors and different porogens. In all these embodiments, process conditions are adjusted so that the low-k dielectric layer 26 and low-k cap layer 28 have k values, porosities and hardnesses similar to those previously discussed. However, the cost is higher if at least one of the precursor and porogens is different.

The preferred embodiments of the present invention have several advantageous features. By forming the low-k dielectric layer and the overlying low-k cap layer in-situ with the similar materials, processes are simplified and cost is reduced. The low-k cap layer in the preferred embodiments of the present invention has good adhesion to the underlying low-k dielectric layer and the overlying ARC layer, thus is substantially free from peeling. Other problems presented in prior methods such as difficulty in removing porogen and damage to the low-k dielectric are also substantially reduced or eliminated.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for forming a dielectric structure, the method comprising:
providing a substrate;
depositing a first low-k dielectric layer comprising a first porogen over the substrate;
depositing a second low-k dielectric layer comprising a second porogen on the first low-k dielectric layer; and
curing the first and the second low-k dielectric layers simultaneously to remove the first and the second porogens and to create a first porosity in the first low-k dielectric layer and a second porosity in the second low-k dielectric layer, wherein the second porosity is less than the first porosity.

2. The method of claim 1, wherein the first and the second porogens comprise same materials, and wherein the deposition of the first low-k dielectric layer and the second low-k dielectric layer comprise a common set of precursors.

3. The method of claim 2, wherein a porogen percentage in the second low-k dielectric layer is less than a porogen percentage in the first low-k dielectric layer by greater than about 5 percent.

4. The method of claim 1, wherein the step of depositing the first low-k dielectric layer comprises a higher porogen-to-precursor ratio than the step of depositing the second low-k dielectric layer.

5. The method of claim 1, wherein the first and the second low-k dielectric layers are formed by a chemical vapor deposition method.

6. The method of claim 1, wherein the step of curing the first and the second low-k dielectric layers is performed using a method selected from the group consisting essentially of ultraviolet curing, eBeam curing, thermal curing, SCCO₂ curing, and combinations thereof.

7. The method of claim 1 further comprising an additional ultraviolet curing process.

8. The method of claim 1, wherein the step of curing is performed in an environment containing a bond-repairing material.

9. The method of claim 8, wherein the bond repairing material comprises a carbon-containing gas.

10. The method of claim 1, wherein the first low-k dielectric layer has a k value of less than about 2.5, and the second low-k dielectric layer has a k value of less than about 2.7.

11. The method of claim 1, wherein the first low-k dielectric layer has a porosity of less than about 25 percent, and the second low-k dielectric layer has a porosity of less than about 35 percent.

12. The method of claim 1, wherein the first low-k dielectric and the second low-k dielectric layer have over 85 percent materials in common.

13. A method for forming a dielectric structure, the method comprising:
providing a substrate;
depositing a low-k dielectric layer comprising a porogen over the substrate;
in-situ depositing a low-k cap layer comprising the porogen on the low-k dielectric layer, wherein the low-k dielectric layer and the low-k cap layer are formed of substantially same precursors; and
curing the low-k dielectric layer and the low-k cap layer simultaneously to remove the porogen and to create a first porosity in the low-k dielectric layer and a second porosity in the low-k cap layer, wherein the second porosity is less than the first porosity.

14. The method of claim 13, wherein the step of depositing the low-k dielectric layer uses a higher RF power than the step of depositing the low-k cap layer.

15. The method of claim 13, wherein the step of depositing the low-k dielectric layer has a higher porogen-to-precursor ratio than the step of depositing the low-k cap layer.

16. The method of claim 13, wherein the step of curing the low-k dielectric layer and the low-k cap layer comprises a first curing and a second curing.

17. The method of claim 16, wherein the first curing is a UV curing using a radiation having a longer wavelength than the second curing.

18. The method of claim 16, wherein the first curing uses a wavelength of between about 250 nm and about 280 nm, and the second curing uses a wavelength of between about 200 nm and about 300 nm.

19. The method of claim 13, wherein the step of curing is performed in an ambient comprising CₓH_{y}.

20. The method of claim 19, wherein CₓH_{y} comprises a material selected from the group consisting essentially of C₂H₄, C₃H₆, HMDS, and combinations thereof.

21. A semiconductor structure comprising:
a substrate;
a low-k dielectric layer over the substrate; and
a low-k cap layer on the low-k dielectric layer, wherein the low-k dielectric layer and the low-k cap layer comprise substantially similar materials, and wherein a first porosity in the low-k dielectric layer is greater than a second porosity in the low-k cap layer.

22. The semiconductor structure of claim 21, wherein the low-k dielectric layer has a k value less than a k value of the low-k cap layer.

23. The semiconductor structure of claim 22, wherein the low-k dielectric layer has a k value of less than about 2.5 and the low-k cap layer has a k value of less than about 2.7.

24. The semiconductor structure of claim 21, wherein the low-k dielectric layer has a porosity of less than about 35 percent and the low-k cap layer has a porosity of less than about 25 percent.

25. The semiconductor structure of claim 21, wherein a hardness of the low-k cap layer is greater than a hardness of the low-k dielectric layer by about 10 percent.

26. The semiconductor structure of claim 21, wherein a porosity of the low-k cap layer is less than a porosity of the low-k dielectric layer by about 1.2 percent.

27. The semiconductor structure of claim 21, wherein the low-k dielectric layer and the low-k cap layer comprises organosilicate glass.

28. The semiconductor structure of claim 21, wherein the low-k dielectric layer and the low-k cap layer comprise a carbon-containing material.

29. The semiconductor structure of claim 21 further comprising a metal feature extending from a top surface of the low-k cap layer to a bottom surface of the low-k dielectric layer.

30. The semiconductor structure of claim 21, wherein the low-k dielectric layer and the low-k cap layer have over 85 percent of materials in common.
